(19) United States
(12) Patent Application Publication
(10) Pub. No.: US 2017/0283249 A1
(43) Pub. Date: Oct. 5, 2017

(54) PIEZOELECTRIC PACKAGE-INTEGRATED SWITCHING DEVICES

(71) Applicant: Intel Corporation, Santa Clara, CA (US)

(72) Inventors: Georgios C. DOGIAMIS, Gilbert, AZ (US); Feras EID, Chandler, AZ (US); Adel A. ELSHERBINI, Chandler, AZ (US); Vijay K. NAIR, Mesa, AZ (US); Telesphor KAMGAING, Chandler, AZ (US); Valluri R. RAO, Saratoga, CA (US); Johanna M. SWAN, Scottsdale, AZ (US)

(21) Appl. No.: 15/088,982

(22) Filed: Apr. 1, 2016

(51) Int. Cl. B81B 7/00

(52) U.S. Cl. CPC B81B 7/0074; B81B 2201/014; B81B 2203/0118; B81B 2203/0307; B81B 2203/04

(57) ABSTRACT

Embodiments of the invention include a switching device that includes an electrode, a piezoelectric material coupled to the electrode, and a movable structure (e.g., cantilever, beam) coupled to the piezoelectric material. The movable structure includes a first end coupled to an anchor of a package substrate having organic layers and a second released end positioned within a cavity of the package substrate.

### FIELD OF THE INVENTION

Embodiments of the present invention relate generally to semiconductor package integrated devices. In particular, embodiments of the present invention relate to piezoelectric semiconductor package integrated switching devices.

### BACKGROUND OF THE INVENTION

Current routing of electrical signals is controlled by different types of switches. For mechanical switches, a number of transduction techniques have been utilized including electrostatic, electromagnetic, thermomechanical, and piezoelectric. Fundamental to most radio frequency (RF) circuits, a switch is used to not only control the path of electrical circuits but also the phase and timing of circuits. The continuous miniaturization of communication systems requires development of smaller, more cost-effective switches for continuous control of a wide variety of electronic signals.

### BRIEF DESCRIPTION OF THE DRAWINGS

FIG. 1 illustrates a view of a microelectronic device 100 having package-integrated piezoelectric devices, according to an embodiment.

FIG. 2 illustrates a package substrate having a package-integrated piezoelectric device, according to an embodiment.

FIG. 3 illustrates a package substrate having a package-integrated piezoelectric device, according to an embodiment.

FIG. 4 illustrates a package substrate having a package-integrated piezoelectric device, according to an embodiment.

FIG. 5 illustrates a package substrate having a package-integrated piezoelectric device, according to an embodiment.

FIG. 6 illustrates a package substrate having a package-integrated piezoelectric device (e.g., n poles, n throws), according to an embodiment.

FIG. 7 illustrates a top view of a package substrate having a package-integrated piezoelectric device (e.g., n poles, n throws), according to an embodiment.

FIG. 8 illustrates a package substrate having a package-integrated piezoelectric device (e.g., single pole, double throws), according to an embodiment.

FIG. 9A illustrates a top view of a package substrate having a package-integrated piezoelectric device, according to an embodiment.

FIG. 9B illustrates a cross sectional view BB′ of the piezoelectric switching device of FIG. 9A.

FIG. 10A illustrates a top view of a package substrate having an interdigitated package-integrated piezoelectric device, according to an embodiment.

FIG. 10B illustrates a cross sectional view CC′ of the piezoelectric switching device of FIG. 10A.

FIGS. 11A-11C illustrate one potential configuration of a package substrate having a cantilever moving in the vertical direction in accordance with one embodiment.

FIG. 12A illustrates a graph of displacement or AC excitation axis 1210 versus time axis 1220 for the switch 1130 in accordance with one embodiment.

FIG. 12B illustrates a graph of a contact 1260 axis having a contact time period 1280 for mechanical contact and electrical connection between the cantilever 1123 and the contact metal 1125 versus time axis 1270.

FIG. 13 illustrates XY (row column) addressing using package-integrated piezoelectric switches in accordance with one embodiment.

FIG. 14 illustrates a reconfigurable RF filter on a package substrate that is based on coupled resonator filters in accordance with one embodiment.

FIG. 15 illustrates a computing device 1500 in accordance with one embodiment of the invention.

### DETAILED DESCRIPTION OF THE INVENTION

Described herein are semiconductor package integrated piezoelectric switching devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order to not obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Micro-electromechanical (MEMS) switches provide a low loss, low power, highly linear, with respect to input power, alternative to existing solid state switch technologies and have dominated the switch market for RF communication systems. Despite these advantages, this technology is very expensive due to the inherent large manufacturing costs of MEMS devices on silicon.

The present design addresses the fabrication of MEMS switches within the semiconductor package substrate that is compatible with high volume package substrate fabrication technology. This present design for MEMS switches integrated in a package substrate is based on our ability to deposit piezoelectric materials in the package substrate and create movable structures in the substrate.

In one embodiment, this technology allows the fabrication of micro-electromechanical piezoelectric switches utilizing substrate manufacturing technology. These switches include released structures such as cantilevers or beams that are free to move in one or more directions and thus opening or closing a signal path. The connection might be a direct conductive connection or based on capacitive coupling of RF signals. The structures contain stacks of piezoelectric material and electrodes that can be used to apply a voltage to the piezoelectric layer. Applying a voltage across the electrodes produces a stress in the piezoelectric material, causing the stack, and thus the entire released structure, to move. This in turn produces the mechanical displacement needed to switch between different paths in the microelectronic system.

The present design results in package-integrated switches, thus enabling smaller and thinner systems in comparison to discrete switches attached to a substrate or board. The package-integrated switches do not add a Z height (along the vertical axis) to a total height of a substrate or multiple substrates. This present design can be manufactured as part of the substrate fabrication process with no need for purchasing and assembling discrete components. It therefore enables high volume manufacturability (and thus lower costs) of systems that need switching devices (e.g., RF Filters, sampling switches, XY array addressing switches, etc). Package-integrated switches also have lower contact resistance in comparison to integrated switches on a silicon substrate with a limited contact area and higher contact resistance.

In one example, the present design includes package-integrated structures to act as RF MEMS switches. Those structures are manufactured as part of the package layers and are made free to move by removing the dielectric material around them. The structures are actuated by piezoelectric stacks that are deposited and patterned layer-by-layer into the package. The present design includes creating functional switches in the package on the principle of suspended and movable structures. Etching of the dielectric material in the package occurs to create cavities. Piezoelectric material deposition (e.g., 0.5 to 1 um deposition thickness) and crystallization also occurs in the package substrate during the package fabrication process. An annealing operation at a lower substrate temperature range (e.g., up to 260° C.) allows crystallization of the piezoelectric material (e.g., lead zirconate titanate (PZT), sodium potassium niobate, AN, ZnO, etc) to occur during the package fabrication process. In one example, laser pulse annealing occurs locally with respect to the piezoelectric material for the annealing operation without damaging other layers of the package substrate (e.g., organic substrate).

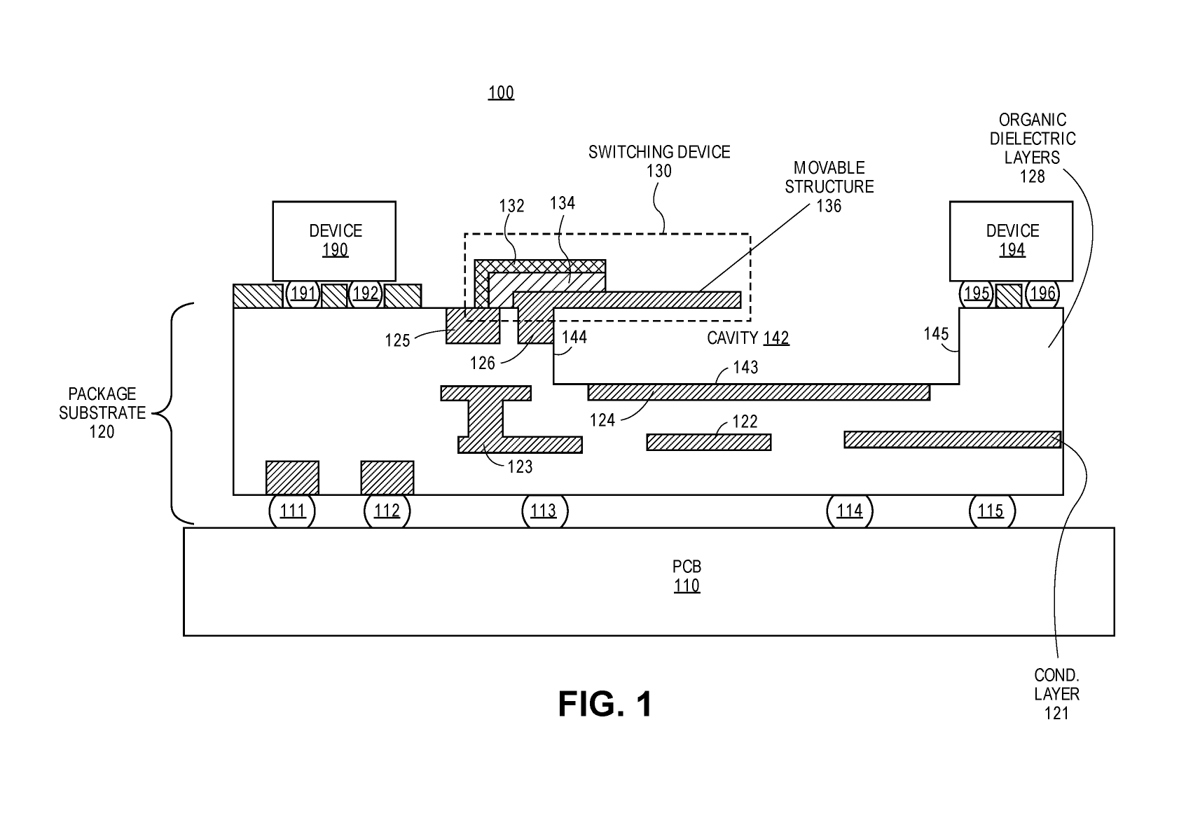

Referring now to FIG. 1, a view of a microelectronic device 100 having package-integrated piezoelectric devices is shown, according to an embodiment of the invention. In one example, the microelectronic device 100 includes multiple devices 190 and 194 (e.g., die, chip, CPU, silicon die or chip, etc.) that are coupled or attached to a package substrate 120 (or printed circuit board 110) with solder balls 191-192, 195-196). The package substrate 120 is coupled or attached to the printed circuit board (PCB) 110 using for example solder balls 111-115.

The package substrate 120 (e.g., organic substrate) includes organic dielectric layers 128 and conductive layers 121-126. Organic materials may include any type of organic material including flame retardant 4 (FR4), resin-filled polymers, prepreg (e.g., pre impregnated, fiber weave impregnated with a resin bonding agent), polymers, silica-filled polymers, etc. The package substrate 120 can be formed during package substrate processing (e.g., panel level). The panels formed can be large (e.g., having in-plane dimensions approximately 0.5 meter by 0.5 meter or greater, etc.) for lower cost. A cavity 142 is formed within the package substrate 120 by removing one or more layers (e.g., organic layers, organic dielectric layers, conductive layers, etc.) from the package substrate 120. The cavity 142 includes a lower member 143 and sidewall members 144-145. In one example, a piezoelectric switching device is formed with a conductive movable structure 136 (e.g., cantilever 136, beam 136), piezoelectric material 134, and a conductive layer 132. The three structures 132, 134, 136 form a stack. The conductive layer 132 can act as a first electrode and the cantilever or beam 136 can act as a second electrode of the piezoelectric device or another electrode can be patterned to act as the second electrode of the device. The cavity 142 can be air-filled or vacuum-filled. Applying a voltage across the electrodes and piezoelectric material produces a stress in the piezoelectric material, causing the entire released structure, to move (e.g., vertically, horizontally, etc.). This in turn produces the mechanical displacement needed to switch between different paths in the microelectronic device 100.

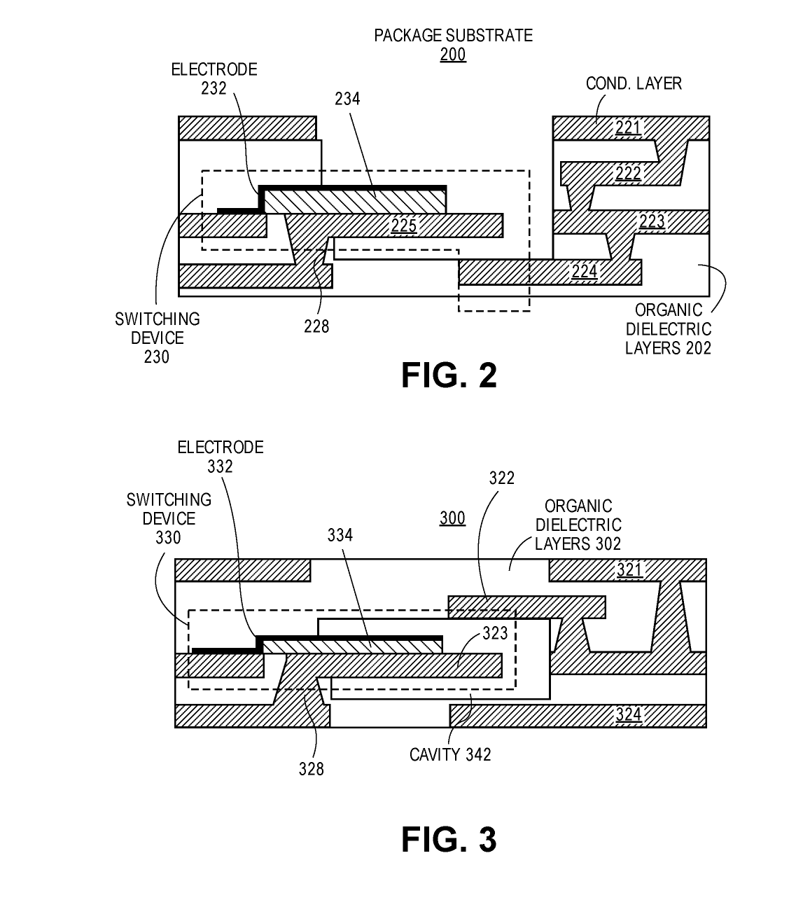

FIG. 2 illustrates a package substrate having a package-integrated piezoelectric device, according to an embodiment of the invention. In one example, the package substrate 200 may be coupled or attached to multiple devices (e.g., die, chip, CPU, silicon die or chip, etc.) and also coupled or attached to a printed circuit board (e.g., PCB 110). The package substrate 200 (e.g., organic substrate) includes organic dielectric layers 202 and conductive layers 221-225 and 232. The package substrate 200 can be formed during package substrate processing (e.g., panel level). A cavity 242 is formed within the package substrate 200 by removing one or more layers (e.g., organic layers, organic dielectric layers, conductive layers, etc.) from the package substrate 200. In one example, a piezoelectric switching device 230 is formed with a conductive movable structure 225 (e.g., cantilever 225, beam 225), piezoelectric material 234, and a conductive layer 232. The conductive layer 232 can act as a first electrode and the cantilever or beam 236 can act as a second electrode of the piezoelectric device. The cavity 242 can be air-filled or vacuum-filled.

In one example, FIG. 2 shows one configuration in which a switching device 230 is created in a metal layer 2 (e.g., layer 225) of the package and can be either a single pole, single throw switch (SPST) or a single pole, double throw (SPDT) switch, providing connection of the metal layer 2 (e.g., layer 225) to the metal layer below and/or above. A number of poles indicates a number of electrically separate switches which are controlled by a single physical actuator. A number of throws indicates a number of separate conductive pathways other than “open” that the switching device can adopt for each pole.

The switching device includes one cantilever 225 coupled to a piezoelectric material 234 that can actuate the cantilever in the vertical direction once a voltage is applied to the electrode 232. The cantilever 225 is anchored on one edge by package connections 228 (e.g., anchors, vias) which serve as both mechanical anchors as well as electrical connections to the rest of the package. A free released end of the cantilever, which experiences the largest displacement when the piezoelectric stack is actuated, is free to move and provides the electrical connection to a conductive layer (e.g., layer 224).

For MEMS, two different types of contacts, namely ohmic and capacitive contacts as illustrated in FIGS. 3, 4, and 5 are possible. FIG. 3 illustrates a package substrate having a package-integrated piezoelectric device, according to an embodiment. In one example, the package substrate 300 may be coupled or attached to multiple devices (e.g., die, chip, CPU, silicon die or chip, etc.) and also coupled or attached to a printed circuit board (e.g., PCB 110). The package substrate 300 (e.g., organic substrate) includes organic dielectric layers 302 and conductive layers 321-324 and 332. The package substrate 300 can be formed during package substrate processing (e.g., panel level). A cavity 342 is formed within the package substrate 300 by removing one or more layers (e.g., organic layers, organic dielectric layers, conductive layers, etc.) from the package substrate 300. In one example, a piezoelectric switching device 330 is formed with a conductive movable structure 323 (e.g., cantilever 323, beam 323), piezoelectric material 334, and a conductive layer 332. The conductive layer 332 can act as a first electrode and the cantilever or beam 323 can act as a second electrode of the piezoelectric device. The cavity 342 can be air-filled or vacuum-filled.

In one example, FIG. 3 shows one configuration in which a switching device 330 is created in a metal layer 2 (e.g., layer 323) of the package and can be either a single pole, single throw switch (SPST) or a single pole, double throw (SPDT) switch, providing connection of the metal layer 2 (e.g., layer 323) to the metal layer below and/or above (e.g., conductive layer 324 and/or 322). The switching device includes one cantilever 323 coupled to a piezoelectric stack that can actuate the cantilever in the vertical direction once a voltage is applied to the stack. The cantilever 323 is anchored on one edge by package connections 328 (e.g., anchors, vias) which serve as both mechanical anchors as well as electrical connections to the rest of the package. A free released end of the cantilever, which experiences the largest displacement when the piezoelectric stack is actuated, is free to move and provides the electrical ohmic connection to a conductive layer (e.g., layer 322). Direct ohmic contacts use two metals to create the switch contact.

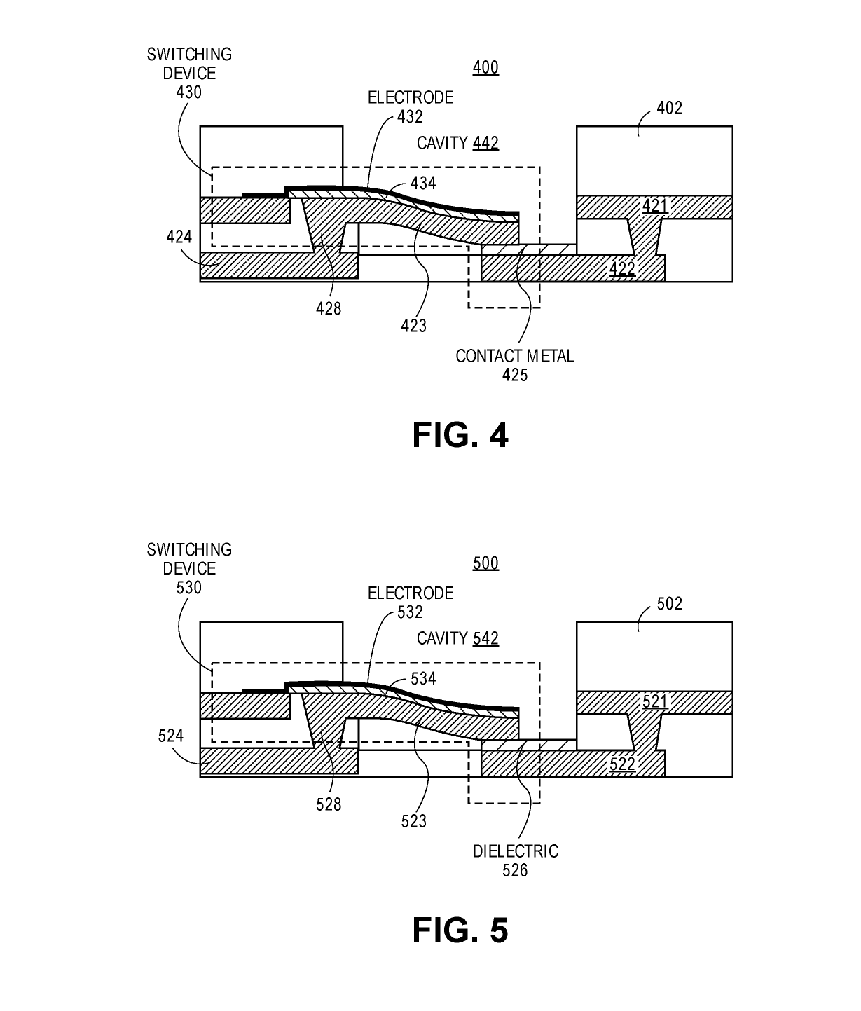

FIG. 4 illustrates a package substrate having a package-integrated piezoelectric device, according to an embodiment. In one example, the package substrate 400 may be coupled or attached to multiple devices (e.g., die, chip, CPU, silicon die or chip, etc.) and also coupled or attached to a printed circuit board (e.g., PCB 110). The package substrate 400 (e.g., organic substrate) includes organic dielectric layers 402 and conductive layers 421-424 and 432. The package substrate 400 can be formed during package substrate processing (e.g., panel level). A cavity 442 is formed within the package substrate 400 by removing one or more layers (e.g., organic layers, dielectric layers, etc.) from the package substrate 400. In one example, a piezoelectric switching device 430 is formed with a conductive movable structure 423 (e.g., cantilever 423, beam 423), piezoelectric material 434, and a conductive layer 432. The conductive layer 432 can act as a first electrode and the cantilever or beam 423 can act as a second electrode of the piezoelectric device. The cavity 442 can be air- or vacuum-filled.

In one example, FIG. 4 shows one configuration in which a switching device 430 is created in a metal layer 2 (e.g., layer 423) of the package and can be either a single pole, single throw switch (SPST) or a single pole, double throw (SPDT) switch, providing connection of the metal layer 2 to the metal layer below and/or above (e.g., conductive layer 422). The switching device includes one cantilever 423 coupled to a piezoelectric material that can actuate the cantilever in the vertical direction once a voltage is applied to the electrode 432. The cantilever 423 is anchored on one edge by package connections 428 (e.g., anchors, vias) which serve as both mechanical anchors as well as electrical connections to the rest of the package. A free released end of the cantilever, which experiences the largest displacement when the piezoelectric stack is actuated, is free to move and provides the electrical ohmic connection to a contact metal layer 425 and a conductive layer (e.g., layer 422).

Capacitive contact switches utilize a dielectric thin film between two metals as illustrated in FIG. 5 which shows a package substrate having a package-integrated piezoelectric device, according to an embodiment. In one example, the package substrate 500 may be coupled or attached to multiple devices (e.g., die, chip, CPU, silicon die or chip, etc.) and also coupled or attached to a printed circuit board (e.g., PCB 110). The package substrate 500 (e.g., organic substrate) includes organic dielectric layers 502 and conductive layers 521-524 and 532. The package substrate 500 can be formed during package substrate processing (e.g., panel level). A cavity 542 is formed within the package substrate 500 by removing one or more layers (e.g., organic layers, dielectric layers, etc.) from the package substrate 500. In one example, a piezoelectric switching device 530 is formed with a conductive movable structure 523 (e.g., cantilever 523, beam 523), piezoelectric material 534, and a conductive layer 532. The conductive layer 532 can act as a first electrode and the cantilever or beam 523 can act as a second electrode of the piezoelectric device. The cavity 542 can be air-filled or vacuum-filled.

In one example, FIG. 5 shows one configuration in which a switching device 530 is created in a metal layer 2 (e.g., layer 523) of the package and can be either a single pole, single throw switch (SPST) or a single pole, double throw (SPDT) switch, providing connection of the metal layer 2 to the metal layer below and/or above (e.g., conductive layer 522). The switching device includes one cantilever 523 coupled to a piezoelectric material that can actuate the cantilever in the vertical direction once a voltage is applied to the electrode 532. The cantilever 523 is anchored on one edge by package connections 528 (e.g., anchors, vias) which serve as both mechanical anchors as well as electrical connections to the rest of the package. A free released end of each cantilever, which experiences the largest displacement when the piezoelectric stack is actuated, is free to move and provides the electrical capacitive connection to a conductive layer (e.g., layer 522) via a dielectric layer 526. This dielectric can be either deposited on the cantilever or on the contact side. At higher frequencies, the RF signal is capacitively coupled through the dielectric layer 526 to the switch path.

Although FIGS. 2-5 show one cantilever, other embodiments can have more than one cantilever connected electrically in parallel and thus resulting in decreased contact resistance. Other embodiments might have different cantilever shapes and different switch configurations such as double pole, double throw (DPDT), four pole, double throw (4PDT) etc. as well as incorporating horizontal vs. vertical motion or any other direction caused by actuation of the piezoelectric stack.

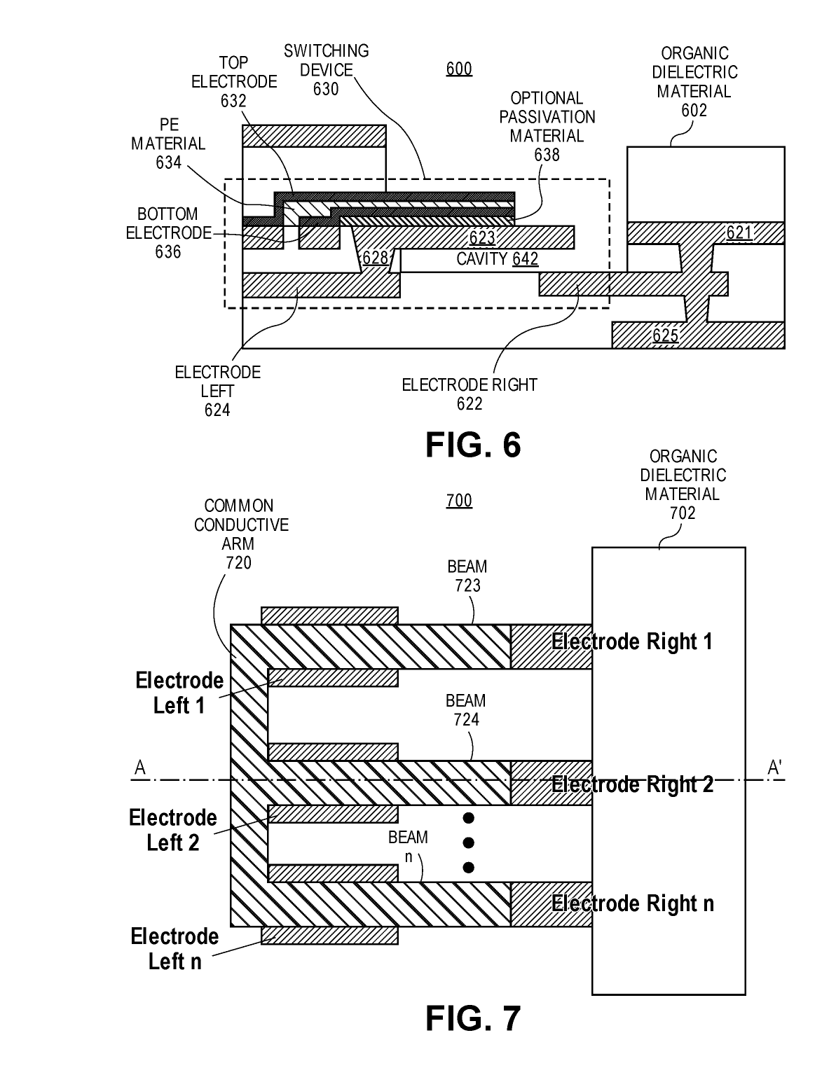

FIG. 6 illustrates a package substrate having a package-integrated piezoelectric device (e.g., n poles, n throws), according to an embodiment. In one example, the package substrate 600 may be coupled or attached to multiple devices (e.g., die, chip, CPU, silicon die or chip, etc.) and also coupled or attached to a printed circuit board (e.g., PCB 110). The package substrate 600 (e.g., organic substrate) includes organic dielectric layers 602 and conductive layers 621-625, 632, and 636. The package substrate 600 can be formed during package substrate processing (e.g., panel level). A cavity 642 is formed within the package substrate 600 by removing one or more layers (e.g., organic layers, dielectric layers, etc.) from the package substrate 600. In one example, a piezoelectric switching device 630 is formed with n conductive movable structures 623 (e.g., cantilevers 623, beams 623), piezoelectric material 634, and conductive layers 632 and 636. The conductive layer 632 can act as a first top electrode and either the movable structure 623 or a separate layer 636 can act as a second bottom electrode of the piezoelectric device. The cavity 642 can be air-filled or vacuum-filled.

In one example, FIG. 6 shows one configuration in which a switching device 630 is created in a metal layer (e.g., layer 623) of the package and can be either a n pole, n throw switch, a single pole, single throw switch (SPST), or a single pole, double throw switch (SPDT), providing connection of the metal layer 623 to the metal layer below and/or above (e.g., conductive layer 622). The movable structure (e.g., layer 623) can be used as the bottom electrode of the piezoelectric stack, or a different conductive layer 636 can be deposited and patterned to act as the bottom electrode of the piezoelectric stack. If a different layer 636 is used then an insulating passivation layer 638 may optionally be deposited between the bottom electrode 636 and the layer 623. The different layers are deposited and patterned sequentially as part of the fabrication process of the stack.

In one example, the switching device includes n cantilevers 623 coupled to a piezoelectric stack that can actuate the cantilevers in the vertical direction once a voltage is applied to the stack. The cantilever 623 is anchored on one edge by package connections 628 (e.g., anchors, vias) which serve as both mechanical anchors as well as electrical connections to the rest of the package. A free released end of each cantilever, which experiences the largest displacement when the piezoelectric stack is actuated, is free to move and provides the electrical connection to a conductive layer (e.g., layer 622).

FIG. 7 illustrates a top view of a package substrate having a package-integrated piezoelectric device (e.g., n poles, n throws), according to an embodiment. FIG. 6 illustrates a cross sectional view AA′ of one of the switching devices in FIG. 7. The package substrate 700 (e.g., organic substrate) includes an organic dielectric material 702, electrodes right 1, 2, . . . n, electrodes left 1, 2, . . . n, and piezo-actuated conductive beams 723, 724, . . . n that are connected to each other by means of a common conductive arm 720. Thus, the package substrate includes n poles, n throws switching devices.

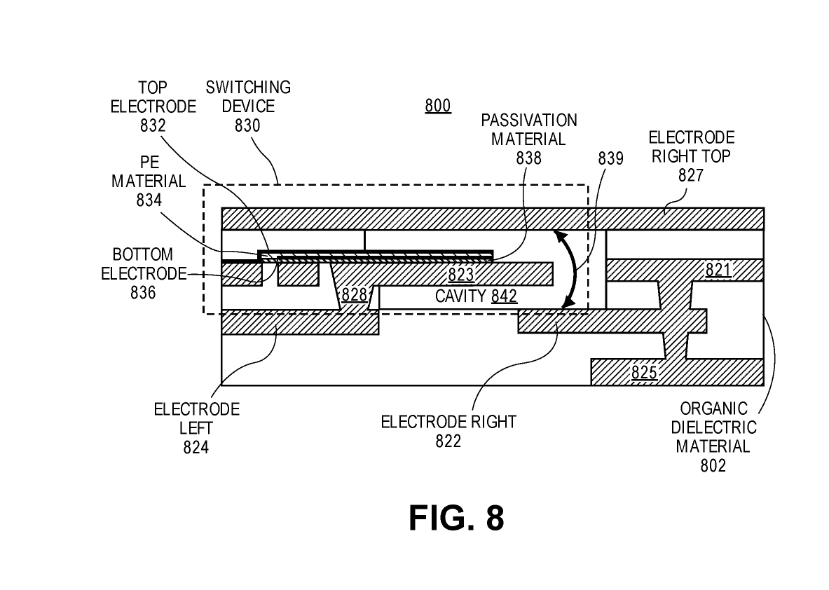

FIG. 8 illustrates a package substrate having a package-integrated piezoelectric device (e.g., single pole, double throws), according to an embodiment. In one example, the package substrate 800 may be coupled or attached to multiple devices (e.g., die, chip, CPU, silicon die or chip, etc.) and also coupled or attached to a printed circuit board (e.g., PCB 110). The package substrate 800 (e.g., organic substrate) includes organic dielectric layers 802 and conductive layers 821-825, 832, and 836. The package substrate 800 can be formed during package substrate processing (e.g., panel level). A cavity 842 is formed within the package substrate 800 by removing one or more layers (e.g., organic layers, dielectric layers, etc.) from the package substrate 800. In one example, a piezoelectric switching device 830 is formed with a single pole conductive movable structure 823 (e.g., cantilever 823, beam 823), piezoelectric material 834, and conductive layers 832 and 836. The conductive layer 832 can act as a first top electrode and either the movable structure 823 or a separate layer 836 can act as a second bottom electrode of the piezoelectric device. The cavity 842 can be air-filled or vacuum-filled.

In one example, FIG. 8 shows one configuration in which a switching device 830 is created in a metal layer (e.g., layer 823) of the package and can be a single pole, double throw switch (SPDT) providing connection of the metal layer 823 to the metal layer below (e.g., electrode right bottom 822) and/or above (e.g., electrode right top 827). The movable structure (e.g. layer 823) can be used as the bottom electrode of the piezoelectric stack, or a different conductive layer 836 can be deposited and patterned to act as the bottom electrode of the piezoelectric stack. If a different layer 836 is used then an insulating passivation layer 838 may optionally be deposited between the bottom electrode 836 and the layer 823. The different layers are deposited and patterned sequentially as part of the fabrication process of the stack.

In one example, the cantilever 823 is anchored on one edge by package connections 828 (e.g., anchors, vias) which serve as both mechanical anchors as well as electrical connections to the rest of the package. A free released end of the cantilever 823, which experiences the largest displacement when the piezoelectric stack is actuated, is free to move with a range of motion 839 and provides the electrical connection to a conductive layer (e.g., layer 822, layer 827).

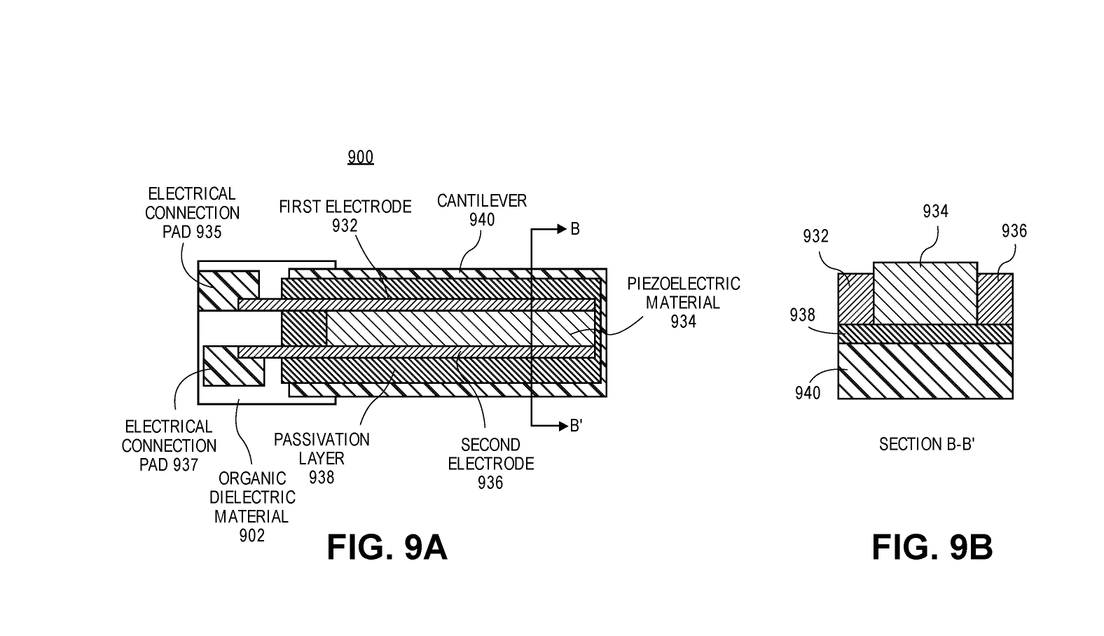

FIG. 9A illustrates a top view of a package substrate having a package-integrated piezoelectric device, according to an embodiment. FIG. 9B illustrates a cross sectional view BB′ of the piezoelectric switching device of FIG. 9A. The package substrate 900 includes an organic dielectric material 902, electrodes 932 and 936, piezoelectric material 934, electrical connection pads 935 and 937, passivation layer 938, and piezo-actuated conductive cantilever 940.

A piezoelectric stack can include a sandwich configuration in which the piezoelectric material 934 is deposited between two electrodes 932 and 936 in the horizontal plane as shown in FIG. 9B. In this configuration, the electrodes are patterned in the same horizontal layer. In this case, applying a voltage across the electrodes in the horizontal plane causes the stack and switch lever (e.g., cantilever 940) to bend in the horizontal plane, producing an in-plane motion, so that the switching happens in the same plane. For this configuration, an insulating passivation layer 938 is needed between the metal lever layer of the switch (e.g., cantilever 940) and the electrodes 932 and 936 so that the electrodes are not electrically shorted. Although not shown in FIG. 9B, a cavity and a pathway for electrical coupling of the cantilever to other structures in the package during switching operations are included as well, similar to previous embodiments discussed.

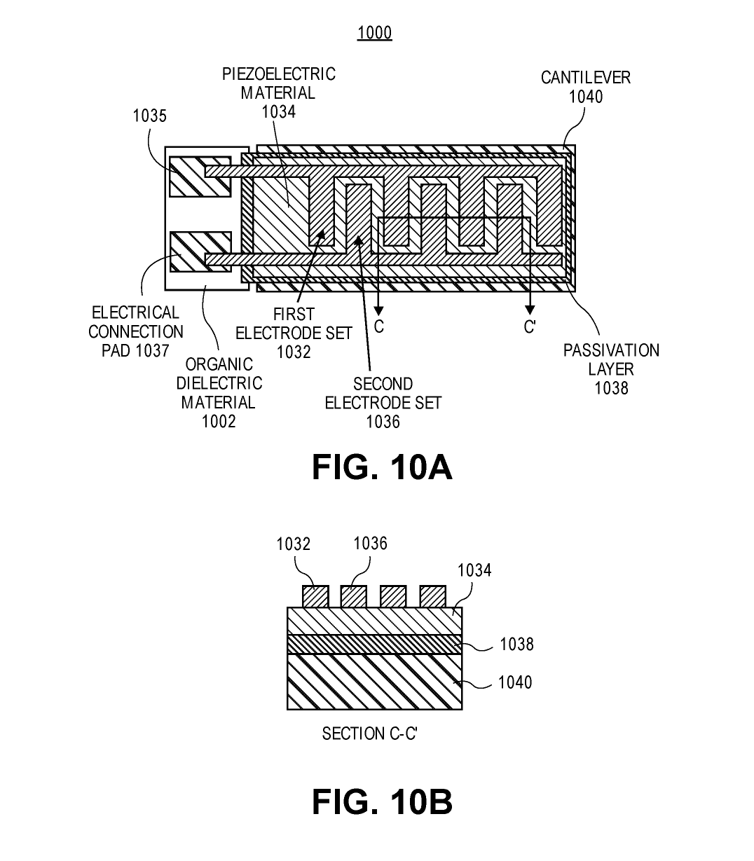

FIG. 10A illustrates a top view of a package substrate having an interdigitated package-integrated piezoelectric device, according to an embodiment. FIG. 10B illustrates a cross sectional view CC′ of the piezoelectric switching device of FIG. 10A. The package substrate 1000 includes an organic dielectric material 1002, electrode sets 1032 and 1036, piezoelectric material 1034, electrical connection pads 1035 and 1037, and piezo-actuated conductive cantilever 1040.

A piezoelectric stack can include a configuration in which the piezoelectric material 1034 is deposited in a layer above or below two interdigitated electrode sets 1032 and 1036 as shown in FIG. 10A. In this configuration, the electrodes are patterned in the same horizontal layer. In this case, applying a voltage across the electrodes in the horizontal plane causes the stack and switch lever (e.g., cantilever 1040) to bend in the vertical direction. For this configuration, an insulating passivation layer 1038 may be deposited between the metal lever layer of the switch (e.g., cantilever 1040) and the piezoelectric material 1034. Although not shown in FIG. 10B, a cavity and a pathway for electrical coupling of the cantilever to other structures in the package during switching operations are included as well, similar to previous embodiments discussed.

The switches described herein can be utilized as dynamic as well as static switches. Since the lever (e.g., cantilever, beam) is suspended, it exhibits (depending on its mass and stiffness) a well defined mechanical natural frequency. Exciting the switch electrodes with an AC voltage at this same natural frequency, an oscillation is induced in the lever at a frequency equal to its natural frequency. Driving the switch at resonance requires less power than off-resonance switching and results in higher displacement amplitudes. This dynamic way of switching can find use in sensor sampling applications in which data is transferred to/from the system at given intervals and only for a small duration at each interval (e.g. temperature or humidity sensor sampling happens at time intervals >10 ms).

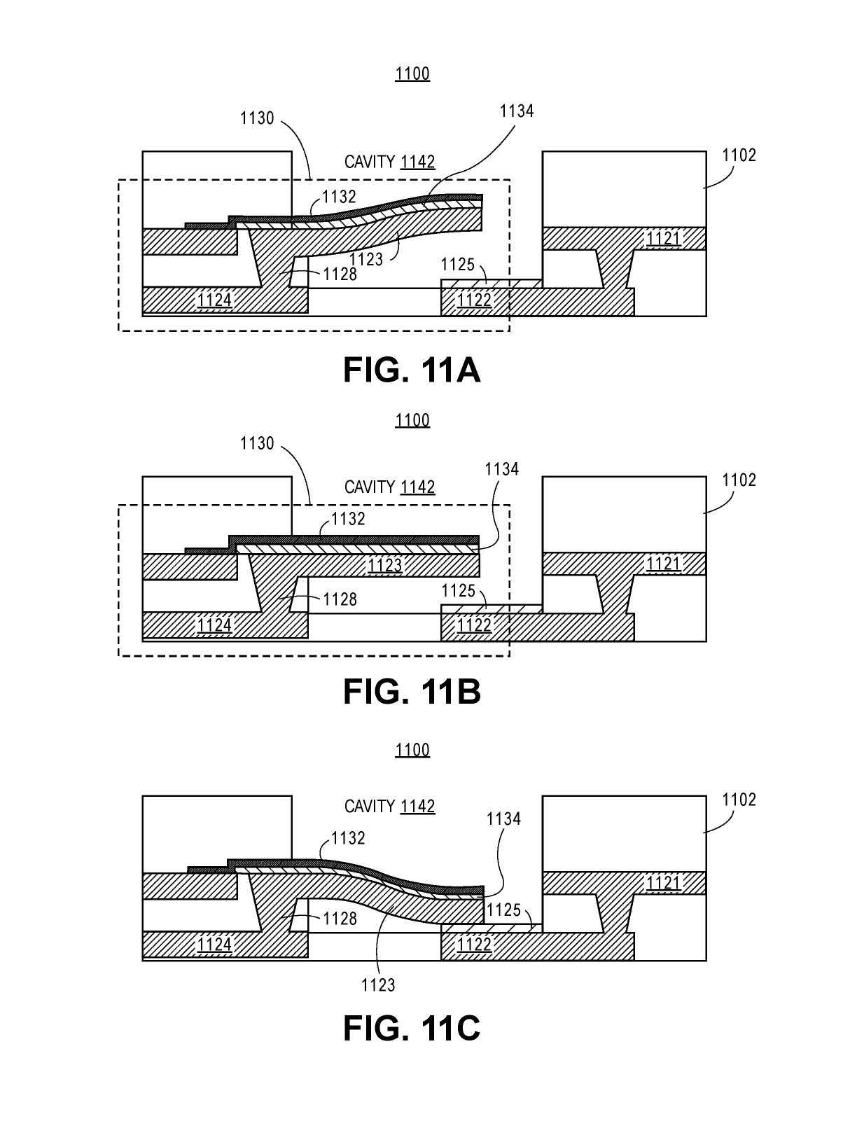

FIGS. 11A-11C illustrate one potential configuration of a package substrate having a cantilever moving in the vertical direction in accordance with one embodiment. The package substrate 1100 includes organic dielectric layers 1102 and conductive layers 1121-1124 and 1132. The package substrate 1100 can be formed during package substrate processing (e.g., panel level). A cavity 1142 is formed within the package substrate 1100 by removing one or more layers (e.g., organic layers, dielectric layers, etc.) from the package substrate 1100. In one example, a piezoelectric switching device 1130 is formed with a conductive movable structure 1123 (e.g., cantilever 1123, beam 1123), piezoelectric material 1134, and a conductive layer 1132. The cavity 1142 can be air-filled or vacuum-filled.

In one example, the switching device includes one cantilever 1123 coupled to a piezoelectric stack that can actuate the cantilever in the vertical direction once a voltage is applied to the stack. The stack contains a top electrode 1132, piezoelectric material 1134, and a bottom electrode. The cantilever 1123 can act as a bottom electrode for the stack, or alternatively, a different conductive layer can be used for the bottom electrode, in which case an insulating material may be optionally deposited between the cantilever and the bottom electrode. The cantilever 1123 is anchored on one edge by package connections 1128 (e.g., anchors, vias) which serve as both mechanical anchors as well as electrical connections to the rest of the package. A free released end of the cantilever, which experiences the largest displacement when the piezoelectric stack is actuated, is free to move and provides the electrical ohmic connection to a contact metal layer 1125 and a conductive layer (e.g., layer 1122).

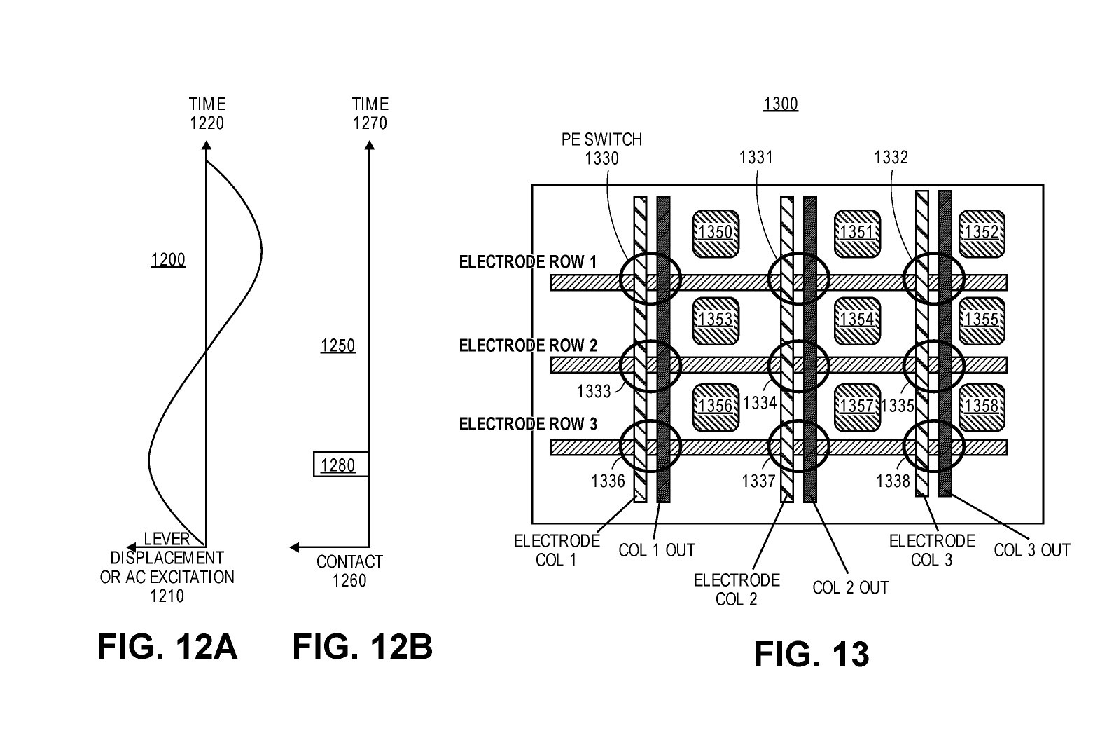

FIGS. 11A-11C illustrate driving the switch 1130 dynamically at its natural resonance frequency. The geometry of the switch 1130 determines the frequency of its natural mechanical resonance. FIG. 12A illustrates a graph 1200 of lever displacement or AC excitation axis 1210 versus time axis 1220 for the switch 1130 in accordance with one embodiment. FIG. 12B illustrates a graph 1250 of a contact 1260 axis having a contact time period 1280 for mechanical contact and electrical connection between the cantilever 1123 and the contact metal 1125 versus time axis 1270. Achieving contact only during the short period of time 1280 can be ideal for sampling applications or for low power sensor readout.

In another embodiment the cantilever can move in the horizontal direction, or can be replaced with a clamped-clamped suspended beam moving in either the horizontal or vertical directions.

FIG. 13 illustrates XY (row, column) addressing using package-integrated piezoelectric switches in accordance with one embodiment. A package substrate 1300 includes an array of switches 1330-1338 for addressing an array of similar or different types of devices 1350-1358 (e.g., chips, CPUs, dies, imaging array, antennas of RF imaging array, etc.). The switches can be any of the switches described herein with each switch being fabricated at each intersection of rows 1-3 and columns 1-3 of the array of the package 1300. Choosing a row electrode and a column electrode allows actuating only the switch that has both electrodes driven, thus closing the path between a device 1350-1358 coupled to the actuated switch and a corresponding output column. For example, driving with a voltage the row electrode 1 and the column electrode 3, the switch 1332 will be actuated. It will then close/short the output of the device 1352 to the vertical column 3 output and hence this output can be read out with a custom designed circuit. The device outputs can be selectively routed to the vertical shared output columns, depending on which of the switches is actuated.

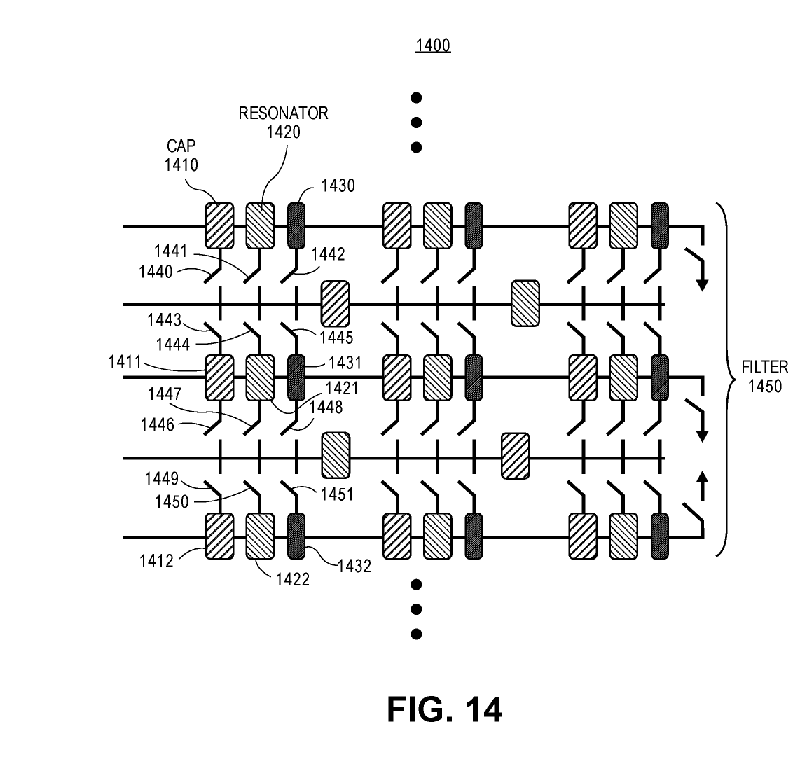

Wireless communication systems utilize different filters to accommodate different communication standards (e.g., 2G, 3G, 4G, LTE, 5G), different frequency bands according to location, as well as different communication protocols (e.g., WiFi, Bluetooth, GPS). FIG. 14 illustrates a reconfigurable RF filter on a package substrate that is based on coupled resonator filters in accordance with one embodiment. Other embodiments might include different filter structures. Here the switches can be used to connect different capacitors or passives to different resonators, allowing the selection of different bands and/or protocols. The package 1400 includes rows of capacitors (e.g., 1410-1412), resonators (e.g., 1420-1422), shorting wires or connectors (e.g., 1430-1432), and piezoelectric switches (e.g.,1440-1451) for controlling which capacitors and resonators will be used for the reconfigurable RF filter for a particular RF application.

Other embodiments include simple mechanical switches to be actuated to connect different subsystems of a larger system, such as connecting/isolating the battery to a system. Other embodiments might include the creation of reconfigurable diplexers/triplexers, etc. Diplexers are typically used with radio receivers or transmitters on different, widely separated, frequency bands.

It will be appreciated that, in a system on a chip embodiment, the die may include a processor, memory, communications circuitry and the like. Though a single die is illustrated, there may be none, one or several dies included in the same region of the microelectronic device.

In one embodiment, the microelectronic device may be a crystalline substrate formed using a bulk silicon or a silicon-on-insulator substructure. In other implementations, the microelectronic device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of the present invention.

The microelectronic device may be one of a plurality of microelectronic devices formed on a larger substrate, such as, for example, a wafer. In an embodiment, the microelectronic device may be a wafer level chip scale package (WLCSP). In certain embodiments, the microelectronic device may be singulated from the wafer subsequent to packaging operations, such as, for example, the formation of one or more sensing devices.

One or more contacts may be formed on a surface of the microelectronic device. The contacts may include one or more conductive layers. By way of example, the contacts may include barrier layers, organic surface protection (OSP) layers, metallic layers, or any combination thereof. The contacts may provide electrical connections to active device circuitry (not shown) within the die. Embodiments of the invention include one or more solder bumps or solder joints that are each electrically coupled to a contact. The solder bumps or solder joints may be electrically coupled to the contacts by one or more redistribution layers and conductive vias.

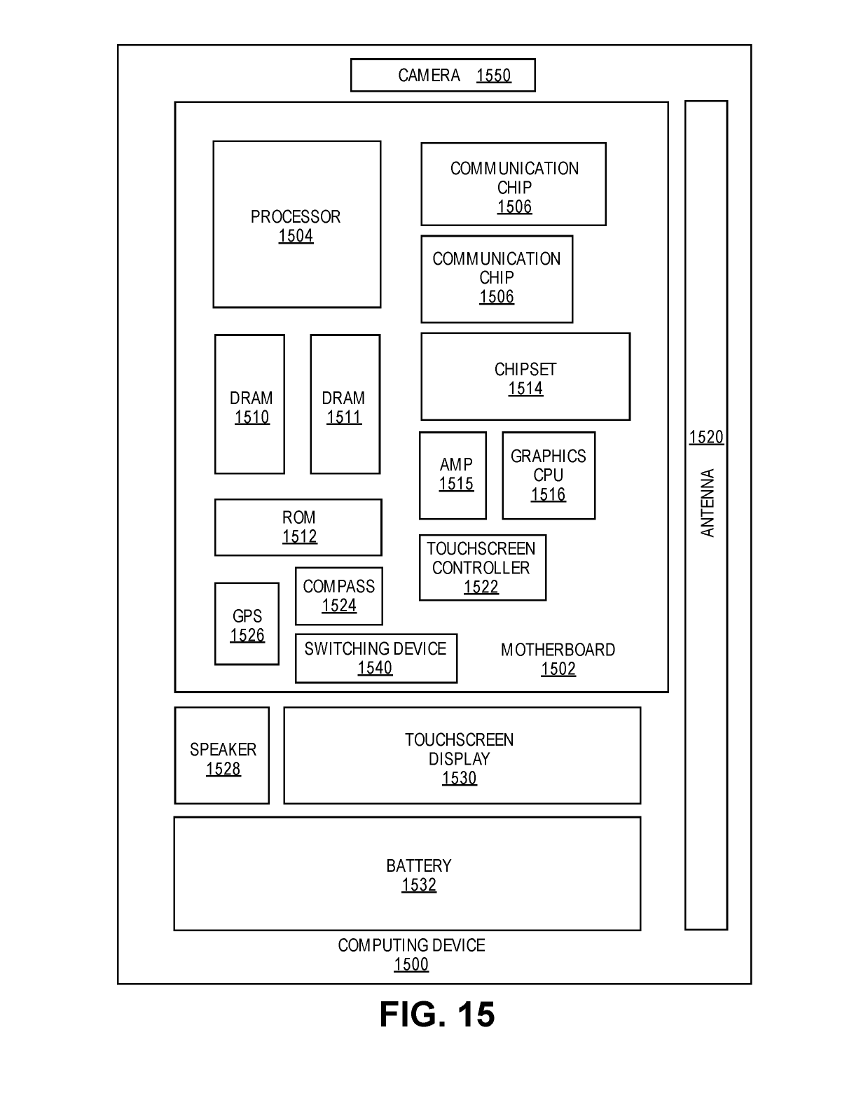

FIG. 15 illustrates a computing device 1500 in accordance with one embodiment of the invention. The computing device 1500 houses a board 1502. The board 1502 may include a number of components, including but not limited to a processor 1504 and at least one communication chip 1506. The processor 1504 is physically and electrically coupled to the board 1502. In some implementations the at least one communication chip 1506 is also physically and electrically coupled to the board 1502. In further implementations, the communication chip 1506 is part of the processor 1504.

Depending on its applications, computing device 1500 may include other components that may or may not be physically and electrically coupled to the board 1502. These other components include, but are not limited to, volatile memory (e.g., DRAM 1510, 1511), non-volatile memory (e.g., ROM 1512), flash memory, a graphics processor 1516, a digital signal processor, a crypto processor, a chipset 1514, an antenna 1520, a display, a touchscreen display 1530, a touchscreen controller 1522, a battery 1532, an audio codec, a video codec, a power amplifier 1515, a global positioning system (GPS) device 1526, a compass 1524, a switching device 1540 (e.g., an piezoelectric switching device), a gyroscope, a speaker, a camera 1550, and a mass storage device (such as hard disk drive, compact disk (CD), digital versatile disk (DVD), and so forth).

The communication chip 1506 enables wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1500 may include a plurality of communication chips 1506. For instance, a first communication chip 1506 may be dedicated to shorter range wireless communications such as Wi-Fi, WiGig and Bluetooth and a second communication chip 1506 may be dedicated to longer range wireless communications such as GPS, EDGE, GPRS, CDMA, WiMAX, LTE, Ev-DO, 5G, and others.

The processor 1504 of the computing device 1500 includes an integrated circuit die packaged within the processor 1504. In some implementations of the invention, the integrated circuit processor package or motherboard 1502 includes one or more devices, such as switching devices in accordance with implementations of embodiments of the invention. The term “processor” may refer to any device or portion of a device that processes electronic data from registers and/or memory to transform that electronic data into other electronic data that may be stored in registers and/or memory. The communication chip 1506 also includes an integrated circuit die packaged within the communication chip 1506.

The following examples pertain to further embodiments. Example 1 is a switching device comprising an electrode, a piezoelectric material coupled to the electrode, and a cantilever coupled to the piezoelectric material. The cantilever includes a first end coupled to an anchor of a package substrate having organic layers and a second released end positioned within a cavity of the package substrate.

In example 2, the subject matter of example 1 can optionally include the released end of the cantilever moving from a first position to a second position for actuation of the switching device upon application of voltage between the electrode and the cantilever.

In example 3, the subject matter of any of examples 1-2 can optionally further include the released end of the cantilever is suspended in the cavity while in the first position and the released end of the cantilever forms an ohmic contact with a conductive layer while in the second position to form a conductive pathway.

In example 4, the subject matter of any of examples 1-2 can optionally further include the released end of the cantilever contacting a dielectric layer that is coupled to a conductive layer while in the second position to form an electrical coupling pathway upon application of certain radio frequency signals.

In example 5, the subject matter of any of examples 1-4 can optionally have the cantilever function as part of a single pole, single throw switching device or a single pole, double throw switching device.

In example 6, the subject matter of any of examples 1-5 can optionally include the electrode and piezoelectric material are designed to actuate a plurality of cantilevers in the cavity.

In example 7, the subject matter of example 6 can optionally have released ends of the plurality of cantilevers move from the first position to the second position in a vertical direction for actuation of the switching device upon application of voltage to the electrode.

In example 8, the subject matter of any of examples 1-7 can optionally have the switching device being integrated with the package substrate during panel level fabrication of the package substrate.

In example 9, the subject matter of any of examples 1-7 can optionally have the switching device being capable of being dynamically driven at or close to its natural resonance frequency.

Example 10 is a package substrate comprising a plurality of organic dielectric layers and a plurality of conductive layers to form the package substrate, a cavity formed in the package substrate, and a piezoelectric switching device integrated within the package substrate. The piezoelectric switching device includes a piezoelectric material that is coupled to first and second electrodes and a movable structure that is mechanically coupled to one of the electrodes. The movable structure includes a released end positioned within the cavity and being capable of switching from a first position to a second position based on actuation of the piezoelectric switching device.

In example 11, the subject matter of example 10 can optionally include a passivation material positioned to electrically isolate one of the electrodes and the movable structure.

In example 12, the subject matter of any of examples 10-11 can optionally further include the released end of the movable structure moving from a first position to a second position for actuation of the switching device upon application of a voltage differential between the first and second electrodes.

In example 13, the subject matter of any of examples 10-12 can optionally further include the released end of the movable structure being suspended in the cavity while in the first position and the released end of the movable structure forming an ohmic contact with a conductive layer while in the second position to form a conductive pathway.

In example 14, the subject matter of any of examples 10-12 can optionally further include the released end of the movable structure contacting a dielectric layer that is coupled to a conductive layer while in the second position to form an electrical coupling pathway upon application of certain radio frequency signals.

In example 15, the subject matter of any of examples 10-14 can optionally further include the first and second electrodes and piezoelectric material being designed to actuate a plurality of movable structures in the cavity.

In example 16, the subject matter of any of examples 10-15 can optionally further include the first and second electrodes and piezoelectric material are designed to actuate the movable structure in a horizontal range of motion in plane of the package substrate.

In example 17, the subject matter of any of examples 10-15 can optionally further include the first and second electrodes and piezoelectric material being designed to actuate the movable structure in a vertical range of motion with respect to the package substrate.

In example 18, the subject matter of any of examples 10-16 can optionally further include the first and second electrodes are patterned in the same horizontal layer in an interdigitated configuration.

In example 19, the subject matter of any of examples 10-16 and 18 can optionally further include the first electrode, the second electrode, and the piezoelectric material are all patterned in the same horizontal plane.

Example 21 is a computing device comprising at least one processor to process data and a package substrate coupled to the at least one processor. The package substrate includes a plurality of organic dielectric layers and a plurality of conductive layers to form the package substrate which includes a piezoelectric switching device having a piezoelectric material that is coupled to an electrode and a movable structure. The movable structure includes a released end positioned within a cavity of the package substrate and being capable of switching from a first position to a second position based on actuation of the piezoelectric switching device.

In example 22, the subject matter of example 21 can optionally further include a printed circuit board coupled to the package substrate.

In example 23, the subject matter of any of examples 21-23 can optionally further include the released end of the movable structure moving from a first position to a second position for actuation of the switching device upon application of voltage to the electrode.

1. A switching device, comprising:
an electrode;
a piezoelectric material coupled to the electrode; and
a cantilever coupled to the piezoelectric material, the cantilever having a first end coupled to an anchor of a package substrate having organic layers and a second released end positioned within a cavity of the package substrate.

2. The switching device of claim 1, wherein the released end of the cantilever moves from a first position to a second position for actuation of the switching device upon application of voltage between the electrode and the cantilever.

3. The switching device of claim 2, wherein the released end of the cantilever is suspended in the cavity while in the first position and the released end of the cantilever forms an ohmic contact with a conductive layer while in the second position to form a conductive pathway.

4. The switching device of claim 2, wherein the released end of the cantilever contacts a dielectric layer that is coupled to a conductive layer while in the second position to form an electrical coupling pathway upon application of certain radio frequency signals.

5. The switching device of claim 1, wherein the cantilever functions as part of a single pole, single throw switching device or a single pole, double throw switching device.

6. The switching device of claim 1, wherein the electrode and piezoelectric material are designed to actuate a plurality of cantilevers in the cavity.

7. The switching device of claim 6, wherein released ends of the plurality of cantilevers move from the first position to the second position in a vertical direction for actuation of the switching device upon application of voltage to the electrode.

8. The switching device of claim 1, wherein the switching device is integrated with the package substrate during panel level fabrication of the package substrate.

9. The switching device of claim 1, wherein the switching device is capable of being dynamically driven at or close to its natural resonance frequency

10. A package substrate comprising:
a plurality of organic dielectric layers and a plurality of conductive layers to form the package substrate;
a cavity formed in the package substrate; and
a piezoelectric switching device integrated within the package substrate, the piezoelectric switching device having a piezoelectric material that is coupled to first and second electrodes and a movable structure that is mechanically coupled to one of the electrodes, the movable structure having a released end positioned within the cavity and being capable of switching from a first position to a second position based on actuation of the piezoelectric switching device.

11. The package substrate of claim 10, further comprising:
a passivation material positioned to electrically isolate one of the electrodes and the movable structure.

12. The package substrate of claim 10, wherein the released end of the movable structure moves from a first position to a second position for actuation of the switching device upon application of a voltage differential between the first and second electrodes.

13. The package substrate of claim 10, wherein the released end of the movable structure is suspended in the cavity while in the first position and the released end of the movable structure forms an ohmic contact with a conductive layer while in the second position to form a conductive pathway.

14. The package substrate of claim 12, wherein the released end of the movable structure contacts a dielectric layer that is coupled to a conductive layer while in the second position to form an electrical coupling pathway upon application of certain radio frequency signals.

15. The package substrate of claim 10, wherein the first and second electrodes and piezoelectric material are designed to actuate a plurality of movable structures in the cavity.

16. The package substrate of claim 10, wherein the first and second electrodes and piezoelectric material are designed to actuate the movable structure in a horizontal range of motion in plane of the package substrate.

17. The package substrate of claim 10, wherein the first and second electrodes and piezoelectric material are designed to actuate the movable structure in a vertical range of motion with respect to the package substrate.

18. The package substrate of claim 10, wherein the first and second electrodes are patterned in the same horizontal layer in an interdigitated configuration.

19. The package substrate of claim 10, wherein the first electrode, the second electrode, and the piezoelectric material are all patterned in the same horizontal plane.

20. A computing device comprising:
at least one processor to process data; and
a package substrate coupled to the at least one processor, the package substrate includes a plurality of organic dielectric layers and a plurality of conductive layers to form the package substrate which includes a piezoelectric switching device having a piezoelectric material that is coupled to an electrode and a movable structure, the movable structure having a released end positioned within a cavity of the package substrate and being capable of switching from a first position to a second position based on actuation of the piezoelectric switching device.

21. The computing device of claim 20, further comprising:
a printed circuit board coupled to the package substrate.

22. The computing device of claim 20, wherein the released end of the movable structure moves from a first position to a second position for actuation of the switching device upon application of voltage to the electrode.
